(19) United States
(12) Patent Application Publication
(10) Pub. No.: US 2015/0075850 A1
(43) Pub. Date: Mar. 19, 2015

(54) METAL OXIDE ETCHING SOLUTION AND AN ETCHING METHOD

(71) Applicant: Kanto Kagaku Kabushiki Kaisha, Tokyo (JP)

(72) Inventors: Takuo Ohwada, Soka-shi (JP); Toshikazu Shimizu, Soka-shi (JP)

(73) Assignee: Kanto Kagaku Kabushiki Kaisha, Tokyo (JP)

(21) Appl. No.: 14/489,528

(22) Filed: Sep. 18, 2014

(30) Foreign Application Priority Data
Sep. 18, 2013 (JP) 2013-193440

(51) Int. Cl. C09K 13/06; H01L 21/465; H05K 1/09; C09K 13/00; C09K 13/04

(52) U.S. Cl. CPC C09K 13/06; C09K 13/00; C09K 13/04; H05K 1/09; H01L 21/465; H05K 2201/0326
USPC 174/257; 252/79.1; 252/79.2; 252/79.4; 423/624; 423/594.14; 438/104

(57) ABSTRACT

The object of the present invention is to provide an etching solution composition for etching a metal oxide containing In and a metal oxide containing Zn and In used as a transparent electrode or an oxide semiconductor of an electronic device such as a semiconductor element or a flat panel display (FPD), the etching solution composition being controllable to give a practical etching rate, having high dissolving power toward Zn, and enabling a long solution life due to suppressed variation of the formulation during use. The object is solved by an etching solution composition that enables microfabrication to be carried out for a metal oxide containing In and a metal oxide containing Zn and In used as a transparent electrode or an oxide semiconductor of an electronic device such as a semiconductor element or an FPD, the composition containing water and at least one type of acid, excluding hydrohalic acids, perhalic acids, etc., having an acid dissociation constant pKaₙ at 25° C. in any dissociation stage of no greater than 2.15, and the composition having a pH at 25° C. of no greater than 4, and an etching method using the etching solution composition.

### TECHNICAL FIELD

The present invention relates to an etching solution composition for a metal oxide used as a transparent electrode or an oxide semiconductor of an electronic device such as a semiconductor element or a flat panel display (FPD), and an etching method using the etching solution composition.

### BACKGROUND ART

In recent years, amid the progress of miniaturization, weight reduction, and reduction in power consumption of electronic equipment, in the FPD field the introduction of an oxide semiconductor as a channel material for a thin film transistor (TFT) has been examined as a replacement for amorphous silicon (a-Si), which has been widely used in liquid crystal panels (LCD) for large TVs, etc. or low temperature polysilicon (LT p-Si), which is used in small high definition LCDs, organic EL displays (OELD), etc. Furthermore, with regard to this oxide semiconductor, IGZO, which is formed from indium (In), gallium (Ga), and zinc (Zn), has been used in practice. IGZO shows, even in an amorphous state in which a film is formed at low temperature, high electron mobility (˜10 cm²/(V·s)) and excellent drive stability and uniformity. Furthermore, Non-Patent Document 1 shows that since a film can be formed at 200° C. or lower, film formation on a plastic substrate becomes possible, and the use thereof as a channel material for a TFT of an OELD can enable a flexible display to be realized.

Moreover, as a transparent electrode of an LCD or an OELD, ITO, which is based on indium tin oxide (In—Sn—O), has been used, and the demand therefor has been increasing accompanying the increase in size of FPDs and expansion of the market. Since In is a by-product of Zn thus making it difficult to meet the rapid increase in demand, and the price has not stabilized, the development of a transparent electrode containing no In or having a decreased content thereof is in progress, and those containing zinc, such as an indium zinc oxide (In—Zn—O)-based compound (IZO), an aluminum zinc oxide (Al—Zn—O)-based compound (AZO), and a zinc oxide (Zn—O) compound (ZnO) have been proposed.

Furthermore, it is expected that oxide semiconductors will be applied, depending on their properties, to solar cell materials, light-emitting diode materials, wide bandgap materials, or resistance random access memory materials; a Zn-containing oxide semiconductor such as IGZO has a variety of applications and is attracting much attention.

When these metal oxides are used as an electrode of an electronic device or a microelectronic component of an semiconductor element, etc., it is necessary to form a desired pattern by forming a film on a glass or plastic substrate by a sputtering method. Accompanying the miniaturization and increase in performance of electronic devices in particular, it has become necessary to precisely control the dimensions (Critical Dimension; CD) of the pattern formed, and the microfabrication technique is considered to be very important.

Examples of techniques for forming a fine pattern include dry etching techniques such as reactive ion etching (RIE), and a method in which IGZO is etched using an etching gas containing a hydrocarbon without generating a dry etching residue has been proposed in Patent Documents 1 and 2. Since in dry etching chemically active ions generated in a plasma have the property of advancing in a straight line, they hit the surface of the substance to be processed from the vertical direction, a pattern with dimensions true to a mask pattern of a photoresist, etc. can be obtained, and it is suitable for microfabrication.

However, since dry etching requires expensive vacuum equipment and a high frequency generator, it is disadvantageous in terms of cost and, in addition, there is a possibility that ions in a plasma state will damage the substrate, etc. Furthermore, since the processed pattern cross-section has a shape in which the cross-section is vertical to or nearly vertical to the substrate, it is assumed that, when the pattern is subsequently covered using an insulating film of SiO₂, etc. as an upper layer, a gap might occur between the pattern and the insulating film, or the ease of covering might be degraded. Because of this, the processed pattern shape is often required to maintain the CD as much as possible but to have a tapered shape to some extent, and it is difficult to carry out such control by dry etching.

Furthermore, a method in which a pattern is formed by a lift-off method involving forming a resist pattern in advance, forming a film of an oxide semiconductor by a sputtering method on the entire face of the resist pattern, and subsequently removing the resist to thus form a pattern by leaving the material in the openings has been proposed in Non-Patent Documents 2, 3, 4, and 5.

However, the lift-off method has the problem that a photoresist melts at high temperature and deforms. There is another problem that, when removing the photoresist, the end of the oxide semiconductor pattern curls up, and wiring crossing over pattern ends is then easily disconnected, thus making the yield low. Furthermore, there is the problem that pieces of resist remain after the lift-off to thus contaminate the substrate.

On the other hand, in wet etching employing a chemical reaction such as oxidation-reduction or complexation by means of a component contained in a chemical agent, a pattern can be formed using relatively inexpensive processing equipment such as shower etching equipment or an etching bath for contacting an etching solution and a substance to be processed, and compared with dry etching a pattern can easily be formed by optimizing components of the etching solution, treatment conditions (temperature, time), and treatment method (flow of etching solution during immersion, agitation of substrate, spraying by shower, etc.).

Furthermore, wet etching can form an etched cross section with a tapered shape in many cases since, unlike dry etching, etching progresses isotropically while an etching solution is penetrating underneath a mask pattern of a photoresist, etc.

Conventionally, when forming an electrode or a TFT of an FPD such as an LCD or an OELD, wet etching is employed in most cases, and many etching solutions are used for the formation of oxide semiconductor patterns or transparent electrodes of ITO, etc.

As an etching solution for ITO, Patent Document 3 describes an etching solution in which a polysulfonic acid compound and/or a polyoxyethylene-polyoxypropylene block copolymer are added to oxalic acid for the purpose of suppressing foaming properties and suppressing the generation of etching residue, Patent Document 4 describes an etching solution containing oxalic acid and an alkaline compound, and Patent Document 5 describes an etching solution containing oxalic acid, a naphthalenesulfonic acid condensation product, and monoethanolamine or sulfuric acid. As an ITO etching solution containing no oxalic acid, Patent Document 6 describes an etching solution containing 2-hydroxyethanesulfonic acid and a fluorinated compound, Patent Document 7 describes an etching solution in which sulfuric acid, nitric acid, and an etching adjustment agent are mixed and, as an etching solution for a metal oxide containing Zn and In, Patent Document 8 describes an etching solution for a zinc oxide system containing acetic acid and any one of hydrofluoric acid, hydrochloric acid, and phosphoric acid.

Furthermore, as an etching solution for indium oxide, ITO, IZO, etc., Patent Document 9 described an etching solution containing oxalic acid and a sulfate. Patent Document 10 describes an etching solution containing partially neutralized or completely neutralized oxalic acid for a zinc oxide-based material as a target. As an etching solution for ITO or IZO, Patent Document 11 describes an etching solution containing oxalic acid, hydrochloric acid, and a surfactant.

Moreover, as an etching solution for ITO, IZO, etc., Patent Document 12 describes an alkaline etching solution containing ammonia and hydrogen peroxide. As an etching solution for IGZO, Patent Document 13 describes an etching solution containing at least one type from among acetic acid, citric acid, hydrochloric acid, and perchloric acid.

### PRIOR ART DOCUMENTS

### Non-Patent Documents

[Non-Patent Document 1] K. Miura, T. Ueda, H. Yamaguchi, Toshiba Review, Vol. 67, 1, 2012, p. 34-37
[Non-Patent Document 2] K. Nomura et al., Nature, Vol. 432, 25 Nov. 2004, p. 488-492
[Non-Patent Document 3] Applied Physics Letters, 11 Sep. 2006, Vol. 89, No. 11, pp. 112123-1 to 112123-3
[Non-Patent Document 4] E. M. C. Fortunato et al., Advanced Materials, 2005, 17, No. 5, p. 590-594
[Non-Patent Document 5] P. Barquinha et al., Journal of Non-Crystalline Solid Vol. 352, Issues 9-20, 2006, p. 1749-1752

### Patent Documents

[Patent Document 1] JP, A, 2007-335505
[Patent Document 2] JP, A, 2008-042067
[Patent Document 3] JP, A, 2002-164332
[Patent Document 4] JP, A, 2010-045253
[Patent Document 5] JP, A, 2011-049602
[Patent Document 6] JP, A, 2012-129346
[Patent Document 7] JP, A, 2009-177189
[Patent Document 8] US Patent Application No. 2008/0315193
[Patent Document 9] JP, A, 2011-138937
[Patent Document 10] JP, A, 2010-103214
[Patent Document 11] JP, A, 2010-067823
[Patent Document 12] International Patent Application WO 2009/066750
[Patent Document 13] JP, A, 2008-041695

### DISCLOSURE OF INVENTION

### Problems to be Solved by the Invention

The object of the present invention is to provide, targeted at an etching solution that can be used when forming a fine pattern on a metal oxide containing In or a metal oxide containing In and Zn, a novel genre of etching solution that enables control to be carried out to give a practical etching rate, has high dissolving power toward Zn, has little variation in the formulation during use, and can realize a long solution life, but the present inventors have recognized that this object cannot be attained by the conventional techniques described above because of various problems described below.

For example, Patent Documents 3 to 5 above are targeted only at ITO as the substance to be processed and do not disclose etching of a Zn-containing metal oxide; Zn has low solubility in etching solutions containing oxalic acid as a main component, and there is therefore the problem that the Zn that has already dissolved reprecipitates in the etching solution after it has been allowed to stand for a certain period. In a mass-production factory where electronic devices are produced using a large-size substrate, when such an etching solution is used, it becomes necessary to frequently carry out maintenance such as solution replacement or removal of precipitated Zn, the operability is degraded, and it becomes disadvantageous in terms of cost.

Furthermore, Patent Document 6 above, which discloses an ITO etching solution containing no oxalic acid, uses a fluorine compound, and there is therefore concern about damaging glass in the case of a device using a glass substrate. Moreover, Patent Document 7 above, which describes an etching solution in which sulfuric acid and nitric acid are mixed, has difficulty in terms of application to a fine pattern due to the etching rate being too high when it is used for a Zn-containing metal oxide.

On the other hand, Patent Document 8, which discloses an etching solution for a metal oxide containing Zn and In, describes an etching solution for a zinc oxide system containing acetic acid and any of hydrofluoric acid, hydrochloric acid, and phosphoric acid, but since acetic acid, which has a high vapor pressure, is used, the formulation varies due to evaporation of acetic acid during use, and it is difficult to maintain the etching properties.

Furthermore, with regard to the etching solution containing oxalic acid, hydrochloric acid, and a surfactant disclosed in Patent Document 11 above, due to hydrochloric acid being contained, the solubility of a Zn-containing metal oxide greatly improves, but the etching rate is too high, control therefore becomes difficult, and application to a fine pattern becomes difficult. Moreover, since hydrochloric acid generates hydrogen chloride gas, there is a concern about corrosion of equipment such as an etching installation in a factory.

In the alkaline etching solution disclosed in Patent Document 12 above, the formulation tends to vary due to evaporation of ammonia and decomposition of aqueous hydrogen peroxide, and it is therefore necessary to replace the solution frequently.

In Patent Document 13 above, which discloses an etching solution for IGZO containing at least one type from among acetic acid, citric acid, hydrochloric acid, and perchloric acid, the etching rate for IGZO is too low in an aqueous solution of acetic acid or citric acid, but the etching rate for IGZO is too high in an aqueous solution of hydrochloric acid or perchloric acid, and it is not practical.

It has been recognized that such conventional techniques as described above cannot attain the object of the present invention. Therefore, it is an object of the present invention to provide an etching solution composition for etching a metal oxide containing In or a metal oxide containing Zn and In, used as a transparent electrode or an oxide semiconductor of an electronic device such as a semiconductor element or an FPD, that enables the etching rate of each metal oxide to be controlled at a practical level using the same formulation, that has high dissolving power toward Zn, and that enables a long solution life to be achieved due to suppressed variation of the formulation during use.

### Means for Solving the Problems

While carrying out an intensive investigation in order to solve the above problems, the present inventors have found that, when the dissociation stage of an n-acid (n being an integer of 1 or greater), excluding hydrohalic acids and perhalic acids, is defined as the n^{th} stage, a combination of a specific pKaₙ value of the acid of the dissociation stage and a specific pH value of an etching solution composition can optimize the microfabrication of a metal oxide containing In and a metal oxide containing Zn and In used as a transparent electrode or an oxide semiconductor of an electronic device such as a semiconductor element or an FPD, and can increase the solution life and prevent corrosion of materials surrounding the device, etc., and as a result of further research the present invention has thus been accomplished.

That is, the present invention relates to the following.

[1] An etching solution composition for etching a metal oxide containing indium (In) or a metal oxide containing zinc (Zn) and In, the composition comprising at least one type of acid and water, the acid having an acid dissociation constant pKa at 25° C. in any dissociation stage of no greater than 2.15, and the composition having a hydrogen ion concentration pH at 25° C. of no greater than 4 (excluding an etching solution composition comprising a hydrohalic acid, a perhalic acid, KNO₃, CH₃COOK, KHSO₄, KH₂PO₄, K₂SO₄, K₂HPO₄, or K₃PO₄ and, in the case where the acid is oxalic acid, an etching solution composition comprising at least one type of compound selected from the group consisting of a polysulfonic acid compound, a polyoxyethylene-polyoxypropylene block copolymer, a naphthalenesulfonic acid condensation product, a quaternary ammonium hydroxide, an alkali metal hydroxide, an alkanolamine (excluding triethanolamine), a hydroxylamine, ammonium sulfate, ammonium sulfamate, and ammonium thiosulfate).

[2] The etching solution composition according to [1], wherein the metal oxide further comprises at least one type of element selected from the group consisting of aluminum, gallium, and tin.

[3] The etching solution composition according to [1] or [2], wherein the acid is a mineral acid, a sulfonic acid, or oxalic acid.

[4] The etching solution composition according to [3], wherein the mineral acid is sulfuric acid, sulfamic acid, peroxomonosulfuric acid, phosphoric acid, phosphorous acid, hypophosphorous acid, or nitric acid.

[5] The etching solution composition according to [3], wherein the sulfonic acid is methanesulfonic acid, ethanesulfonic acid, para-toluenesulfonic acid, camphorsulfonic acid, or a naphthalenesulfonic acid/formaldehyde condensation product.

[6] The etching solution composition according to any one of [1] to [5], wherein the etching rate in the thickness direction is no greater than 200 nm/min for a layer consisting of a layer comprising a metal oxide containing In and a layer comprising a metal oxide containing Zn and In.

[7] The etching solution composition according to any one of [1] to [6], wherein it does not comprise acetic acid.

[8] The etching solution composition according to any one of [1] to [7], wherein it further comprises a water-soluble organic solvent.

[9] A method for etching a substrate having on the surface a layer comprising a metal oxide containing In or a metal oxide containing Zn and In using the etching solution composition according to any one of [1] to [8].

[10] A wiring board obtained by etching a substrate having on the surface a layer comprising a metal oxide containing In or a metal oxide containing Zn and In by the method according to [9].

[11] A method for producing a wiring board, the method comprising a step of etching a substrate having on the surface a layer comprising a metal oxide containing In or a metal oxide containing Zn and In using the etching solution composition according to any one of [1] to [8].

### Effects of the Invention

The etching solution composition of the present invention can control, preferably by means of the same formulation, the etching rate for a metal oxide containing In and a metal oxide containing Zn and In used as a transparent electrode or an oxide semiconductor of an electronic device such as an FPD so that it is practical, is suitable for formation of a fine pattern necessary for the production of a high definition display and, furthermore, has high dissolving power toward In and Zn, can suppress reprecipitation of In and Zn in the etching solution, can increase the solution life due to suppression of formation of etching residue, and can contribute to a reduction in cost for the manufacture of a semiconductor element or an FPD.

### BRIEF DESCRIPTION OF DRAWINGS

FIGS. 1 (A)-1 (C) schematically show, for the present Examples, vertical cross-sections of (FIG. 1 (A)) an evaluation substrate 4 comprising a glass substrate 1, a sputtered film 2 formed on the surface thereof from IZO or IGZO, and a resist 3 resist-patterned on the surface of said film, (FIG. 1 (B)) an evaluation substrate 4a formed by subjecting said evaluation substrate 4 to a treatment with the etching solution composition related to the present invention, and (FIG. 1 (C)) an evaluation substrate 4b formed by peeling off the resist 3 of said evaluation substrate 4a.

### MODES FOR CARRYING OUT THE INVENTION

The present invention is explained in detail below by reference to preferred embodiments of the present invention.

In one embodiment the present invention relates to an etching solution composition for etching a metal oxide used as a transparent electrode or an oxide semiconductor of an electronic device such as a semiconductor element or an FPD, in particular a metal oxide containing In or a metal oxide containing Zn and In, the composition comprising at least one type of acid and water, the acid having an acid dissociation constant pKa at 25° C. in any dissociation stage of no greater than 2.15, and the composition having a hydrogen ion concentration pH at 25° C. of no greater than 4 (excluding an etching solution composition comprising a hydrohalic acid, a perhalic acid, KNO₃, CH₃COOK, KHSO₄, KH₂PO₄, K₂SO₄, K₂HPO₄, or K₃PO₄ and, in the case where the acid is oxalic acid, an etching solution composition comprising at least one type of compound selected from the group consisting of a polysulfonic acid compound, a polyoxyethylene-polyoxypropylene block copolymer, a naphthalenesulfonic acid condensation product, a quaternary ammonium hydroxide, an alkali metal hydroxide, an alkanolamine (excluding triethanolamine), a hydroxylamine, ammonium sulfate, ammonium sulfamate, and ammonium thiosulfate).

The ‘metal oxide containing In’ referred to in the present invention includes an In—O compound, and preferably In—Sn—O (ITO), which further contains tin (Sn). Furthermore, the ‘metal oxide containing Zn and In’ includes In—Zn—O (IZO), and preferably In—Ga—Zn—O (IGZO), which further contains gallium (Ga). These metal oxides may contain a small amount of aluminum (Al) as an impurity. These metal oxides are usually used as a substrate that has been formed as a film by a sputtering method.

When a dissociation stage of an n-acid (n is an integer of one or greater) is expressed as the n^{th} stage, the acid, excluding hydrohalic acids and perhalic acids, having a pKaₙ at 25° C. of any one or more stage of no greater than 2.15 used in the present invention acts on the dissolution of IZO, IGZO, etc. It is thought that, although IZO or IGZO is ionized (Zn²⁺) in an acidic solution and dissolves in the solution, the higher the acidity the more rapidly this reaction progresses. Because of this, the smaller the pKa, which represents acidity in aqueous solution, the more effective for dissolution of ZnO, IZO, IGZO, etc. The ‘acid’ in the present invention is a substance, which yields hydrogen ions in water solution, and which includes a monobasic acid and a polybasic acid.

However, a hydrohalic acid such as hydrochloric acid or hydrofluoric acid has high electronegativity and acts more strongly to ionize IZO or IGZO than the other acids do, the etching rate becomes too high, and a pattern sometimes disappears for a fine semiconductor element or an electrode of a high definition display. Furthermore, with regard to perhalic acids, perchloric acid is designated as a Class 6 hazardous material, there is a designated quantity, and storage is restricted. Moreover, periodic acid is expensive, contains a large amount of impurities, and is therefore not suitable as a chemical used in a process for producing an electronic device where a clean surface is required.

In the present invention, the pH at 25° C. of the etching solution composition is no greater than 4, preferably no greater than 3, more preferably −5 to 3, and yet more preferably −2 to 3. Even if an acid having a low pKaₙ is used, if the etching solution composition does not have the property of being acidic, it is difficult for dissolution due to ionization of IZO or IGZO to progress as described above. The pH of the actual etching solution composition varies depending on the type of acid, the content of the acid, and the type and content of other components, but being no greater than 4 is a range that enables a high definition pattern to be formed and allows practical use.

When the metal oxide is IZO, the pH at 25° C. of the etching solution composition is preferably no greater than 3, more preferably −5 to 3, and yet more preferably −3 to 3. It is desirable that the pH is in this range from the viewpoint of the ability to control the etching rate so that it is practical.

Furthermore, when the metal oxide is IGZO, the pH at 25° C. of the etching solution composition is preferably no greater than 4, more preferably −5 to 3, and yet more preferably −3 to 3. It is desirable that the pH is in this range from the viewpoint of the ability to control the etching rate so that it is practical.

The acid used in the present invention is preferably a mineral acid, a sulfonic acid, or oxalic acid.

The mineral acid is not particularly limited, and examples include sulfuric acid, sulfamic acid, peroxomonosulfuric acid, phosphoric acid, phosphorous acid, hypophosphorous acid, and nitric acid; among them sulfuric acid and phosphoric acid are preferable.

Furthermore, the sulfonic acid is not particularly limited, and examples include methanesulfonic acid, ethanesulfonic acid, para-toluenesulfonic acid, camphorsulfonic acid, and a naphthalenesulfonic acid/formaldehyde condensation product; among them methanesulfonic acid and a naphthalenesulfonic acid/formaldehyde condensation product are preferable.

Moreover, these acids have high dissolving power toward indium oxide; oxalic acid in particular has high dissolving power specific thereto due to the formation of a complex with indium ion (In³⁺), and high dissolving power toward a metal oxide containing In and Zn can be maintained by combining it with a mineral acid or a sulfonic acid. Furthermore, when a combination of oxalic acid and one or more types of other acid is used as an etching solution composition toward a metal oxide containing Zn, compared with a case in which oxalic acid is used on its own, the solubility of Zn is higher, and this solubility is maintained for a longer period of time. From such a viewpoint, as the other acid used in combination with oxalic acid, phosphoric acid, nitric acid, and methanesulfonic acid are desirable.

When the metal oxide is IZO, the acid used in the present invention is preferably sulfuric acid, phosphoric acid, methanesulfonic acid, or oxalic acid. This enables control of the etching rate to be practical and gives an effect in suppressing the amount of side etching.

Furthermore, when the metal oxide is IGZO, the acid used in the present invention is preferably sulfuric acid, phosphoric acid, nitric acid, methanesulfonic acid, or oxalic acid. This enables the etching rate to be controlled so that it is practical, and gives an effect in suppressing the amount of side etching.

Furthermore, the content of the acid used in the present invention is not particularly limited as it varies depending on the type of acid and the type and content of other components, but when the etching solution composition is defined as 100 wt % it is preferably 0.1 wt % to 70.0 wt %, more preferably 0.5 wt % to 50 wt %, and yet more preferably 3.0 wt % to 40.0 wt %.

When the metal oxide is IZO, the content of the acid is preferably 1.0 to 50.0 wt %, more preferably 2.0 to 45.0 wt %, and yet more preferably 2.0 to 40.0 wt % when the etching solution composition is defined as 100 wt %. It is desirable for the content of the acid to be in this range from the viewpoint of control of the etching rate and suppression of the amount of side etching.

Furthermore, when the metal oxide is IGZO, the content of the acid is preferably 0.1 to 70.0 wt %, more preferably 0.5 to 60.0 wt %, and yet more preferably 1.0 to 60.0 wt % when the etching solution composition is defined as 100 wt %. It is desirable for the content of the acid to be in this range from the viewpoint of control of the etching rate and suppression of the amount of side etching.

When the content of the acid is at least 0.1 wt %, the etching rate of a metal oxide containing Zn and the time taken to complete etching are both within desirable rages, the productivity improves and, moreover, the amount of side etching is suppressed, thus making processing of a fine pattern easy. Furthermore, when the content is no greater than 70.0 wt %, since the etching rate of a metal oxide containing Zn does not become too high, it is possible to carry out sufficient control of etching and suppress the amount of side etching so that it is within a range that causes no problems.

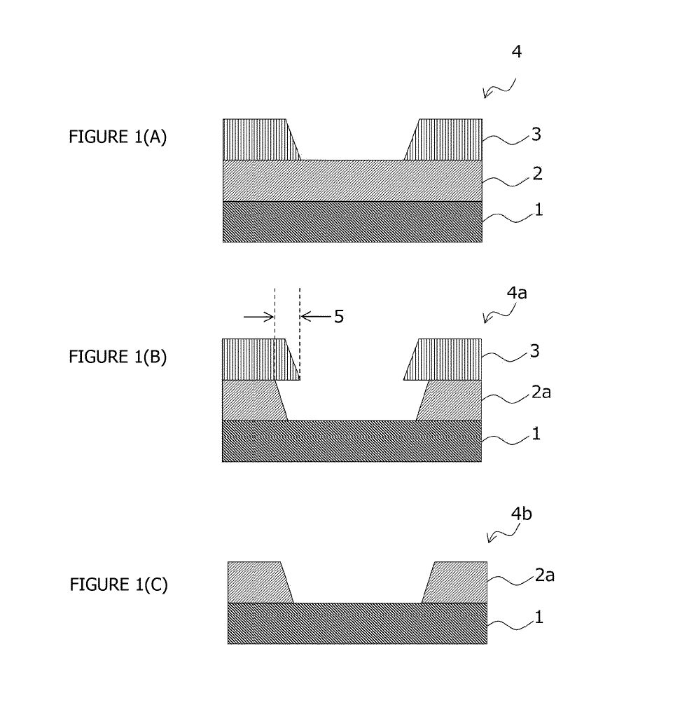

The etching rate for a substrate having on the surface a layer (or film) comprising a metal oxide containing In or a metal oxide containing Zn and In is preferably at least 10 nm/min but no greater than 200 nm/min in the width direction of the layer (or the film), more preferably at least 20 nm/min but no greater than 150 nm/min, yet more preferably at least 30 nm/min but no greater than 150 nm/min, and most preferably at least 50 nm/min but no greater than 150 nm/min. It is desirable for the etching rate to be within this range since the time taken to complete etching (e.g. 1 to 60 minutes) can be made the shortest and the amount of side etching can be minimized. The amount of side etching is preferably no greater than 1.00 μm when it is defined as an amount of side etching 5 in FIG. 1 (B).

Furthermore, the etching solution composition of the present invention preferably does not contain acetic acid. Since acetic acid has a high vapor pressure and easily evaporates, the formulation tends to vary during use due to evaporation of acetic acid, and in order to maintain the etching properties, addition of acetic acid or replacement of the solution is frequently carried out in some cases.

Moreover, the etching solution composition of the present invention may further comprise a water-soluble organic solvent. The water-soluble organic solvent suppresses dissociation of an acid and is used when the etching rate of a metal oxide containing In and a metal oxide containing Zn and In is desirably suppressed. The water-soluble organic solvent is not particularly limited, but examples include, while taking into consideration damage to a resist as a mask, an alcohol, a glycol, and a carboxylic acid.

Examples of the alcohol and glycol include a monohydric aliphatic chain-form alcohol such as 1-butanol, 2-methyl-2-propanol, or diacetone alcohol; a dihydric aliphatic chain-form alcohol such as 1,2-ethanediol, 1,2-propanediol, 1,3-propanediol, 1,3-butanediol, 1,4-butanediol, 2,3-butanediol, or 1,5-pentanediol; a trihydric aliphatic chain-form alcohol such as glycerol; an aliphatic cyclic alcohol such as furfuryl alcohol or tetrahydrofurfuryl alcohol; a glycol such as diethylene glycol, dipropylene glycol, triethylene glycol, tripropylene glycol, propylene glycol monomethyl ether, propylene glycol monoethyl ether, propylene glycol monopropyl ether, propylene glycol n-butyl ether, diethylene glycol monomethyl ether, diethylene glycol monoethyl ether, diethylene glycol n-butyl ether, dipropylene glycol monomethyl ether, dipropylene glycol monoethyl ether, triethylene glycol monomethyl ether, triethylene glycol monoethyl ether, tripropylene glycol monomethyl ether, tripropylene glycol monoethyl ether, or tetraethylene glycol; and derivatives thereof.

Among them, 1,2-ethanediol, 1,2-propanediol, 1,3-propanediol, 1,3-butanediol, 1,4-butanediol, glycerol, diethylene glycol, dipropylene glycol, triethylene glycol, tripropylene glycol, diethylene glycol monomethyl ether, diethylene glycol monoethyl ether, diethylene glycol n-butyl ether, dipropylene glycol monomethyl ether, dipropylene glycol monoethyl ether, triethylene glycol monomethyl ether, triethylene glycol monoethyl ether, tripropylene glycol monomethyl ether, and tripropylene glycol monoethyl ether, which are relatively readily available and inexpensive and have little effect on the human body, are preferable, and among them, 1,2-ethanediol, 1,2-propanediol, glycerol, diethylene glycol, dipropylene glycol, diethylene glycol monomethyl ether, dipropylene glycol monomethyl ether, and tetrahydrofurfuryl alcohol, which are aliphatic alcohols, aliphatic glycols, or derivatives thereof, are particularly preferable.

Examples of the carboxylic acid include lactic acid, glycolic acid, methoxyacetic acid, and ethoxyacetic acid, which have a low vapor pressure, and among them lactic acid and glycolic acid are preferable.

The etching solution composition of the present invention may be produced by any method. For example, the etching solution composition of the present invention may be prepared by adding a component such as the acid to a known etching solution. It may also be prepared by mixing the components with water.

Furthermore, the etching solution composition of the present invention need not be prepared in advance and, for example, it may be prepared by the method described above immediately before carrying out etching.

Moreover, in one embodiment, the present invention also relates to a method for etching a substrate having on the surface a layer or film comprising a metal oxide containing In and a metal oxide containing Zn and In using the etching solution composition as described above, and preferably with the same formulation.

Optimization of the etching temperature and time, conditions for flow of an etching solution during immersion, and conditions for agitating a substrate (including conditions for spraying an etching solution composition onto a substrate as a shower) may be carried out as appropriate by a person skilled in the art, but the temperature, in particular, is preferably 30° C. to 50° C. It is desirable for the temperature to be within this range since evaporation of water, etc. contained in the etching solution composition is suppressed, that is, variation in the concentration of the acid, etc. is small.

Furthermore, in one embodiment, the present invention also relates to a wiring board obtained by etching a substrate having on the surface a layer comprising a metal oxide containing In or a metal oxide containing Zn and In by the etching method described above.

In the present invention, the ‘wiring board’ is a substrate with a desired patterning obtained by subjecting the ‘layer comprising a metal oxide containing In or a metal oxide containing Zn and In’ of the ‘substrate having on the surface a layer comprising a metal oxide containing In or a metal oxide containing Zn and In’ to etching using the etching solution composition related to the present invention, and includes a transparent electrode or an oxide semiconductor of an electronic device such as a semiconductor element or a flat panel display.

The wiring board obtained preferably has patterning, dimensions, and a structure that are suitable for application to a flat panel display, etc.

Moreover, in one embodiment, the present invention also relates to a method for producing a wiring board comprising a step of etching a substrate having on the surface a layer comprising a metal oxide containing In or a metal oxide containing Zn and In, using an etching solution composition related to the present invention described above, and preferably the etching solution composition having the same formulation.

In the etching step included in the production method of the present invention, etching can be carried out under the same etching conditions as those for the etching method described above.

### EXAMPLES

With regard to the etching solution composition of the present invention, the present invention is now explained in detail by reference to Examples and Comparative Examples, but the present invention should not be construed as being limited to these Examples, etc.

### <Evaluation 1: Measurement of Etching Rate of Metal Oxide>

As shown in FIG. 1 (A), a 70 nm film of IZO and a 50 nm film of IGZO were formed on the surface of glass substrates 1 by a sputtering method, the surface of the sputtered film 2 was subjected to resist patterning, thus preparing two types of evaluation substrates 4, and etching solution compositions containing acids at the concentrations shown in Table 1 were prepared.

The evaluation substrate 4 was sectioned into 2.0 cm×2.0 cm pieces and immersed, while agitating, in a polyethylene container containing 50 mL of the etching solution composition at 35° C. for 10 to 60 seconds, and subjected to rinsing with ultrapure water for 1 minute and drying by blowing with nitrogen, thus giving an evaluation substrate 4a (FIG. 1 (B)).

These evaluation substrates 4a were immersed, without agitating, in a glass container containing 50 mL of a resist stripping liquid at 50° C. for 5 minutes, and then subjected again to rinsing with ultrapure water for 1 minute and drying by blowing with nitrogen, thus giving an evaluation substrate 4b (FIG. 1 (C)).

With regard to each evaluation substrate 4b, the amount of various types of metal oxide etched was measured using a stylus profiler, and an etching rate (E.R.) was calculated from the immersion time and the amount of etching. The results thus obtained are shown in Table 1 together with the acid contained in the etching solution composition and its concentration.

TABLE 1
Metal oxide etching rate

| | | | | Etching | | | |
|---|---|---|---|---|---|---|---|
| | | | | solution | | | |
| | | | pKa at | composition | Concentration | Etching rate (nm/min.) | |
| | | Acid | 25° C. | pH | (wt %) | IZO | IGZO |
| Ex. | 1 | Sulfuric acid | −10 | 0.3 | 4.8 | 91 | 124 |
| | 2 | Nitric acid | −1.8 | 0.4 | 3.1 | 60 | 92 |
| | 3 | Phosphoric acid | 1.83 | 1.1 | 4.8 | 57 | 95 |
| | 4 | Sulfamic acid | 0.99 | 0.7 | 4.7 | 35 | 68 |
| | 5 | Methanesulfonic acid | −2.0 | 0.4 | 4.7 | 29 | 52 |
| | 6 | Oxalic acid | 1.27 | 0.9 | 4.4 | 98 | 138 |
| | 7 | Naphthalenesulfonic acid | — | 1.4 | 2.0 | 23 | 50 |
| | | formaldehyde condensation product | | | | | |
| | 8 | Phosphoric acid | 1.83 | 1.0 | 5.0 | 51 | 90 |
| | | Glycolic acid | 3.83 | | 9.0 | | |
| | 9 | Methanesulfonic acid | −2.0 | 0.0 | 9.0 | 15 | 32 |
| | | Lactic acid | 3.79 | | 8.0 | | |
| Comp. | 1 | Hydrochloric acid | −3.7 | 0.4 | 1.8 | 274 | 360 |
| Ex. | 2 | Acetic acid | 4.75 | 2.5 | 3.0 | <10 | <10 |
| | 3 | Iodic acid | 0.75 | 0.7 | 8.2 | <10 | <10 |
| | 4 | Citric acid | 3.09 | 1.6 | 5.7 | <10 | <10 |
| | 5 | Hydrofluoric acid | 2.67 | 2.3 | 1.0 | 1080 | 1200 |
| | 6 | Boric acid | 9.24 | 4.1 | 3.1 | <10 | <10 |
| | 7 | Aqueous ammonia | 9.10 | 11.4 | 0.9 | <10 | <10 |
| | 8 | Potassium dihydrogenphosphate | 7.20 | 4.3 | 5.0 | <10 | <10 |
| | 9 | Ammonium sulfamate | — | 5.0 | 5.0 | <10 | <10 |
| | 10 | Potassium hydroxide | 16 | 13.5 | 2.5 | <10 | <10 |
| | 11 | Tetramethylammonium hydroxide | — | 13.2 | 2.5 | <10 | <10 |

### <Evaluation 2: IGZO Etching Properties Due to pH Variation>

An evaluation substrate 4 having a sputtered film 2 formed from IGZO was prepared in the same way as for <Evaluation 1> (FIG. 1 (A)).

With regard to each of the etching solution compositions, the pH of an aqueous solution of diammonium hydrogenphosphate (6.4 wt %, 50 mL) was measured using a pH meter, and one whose pH had been adjusted to a predetermined pH by the dropwise addition of phosphoric acid was used.

The evaluation substrate 4 was immersed, while agitating, at 35° C. for 10 to 60 seconds in each etching solution composition whose pH had been adjusted, and subjected to rinsing with ultrapure water for 1 minute and drying by blowing with nitrogen, thus giving an evaluation substrate 4a (FIG. 1 (B)).

The evaluation substrate 4a was immersed, without agitating, in a glass container containing 50 mL of a resist stripping liquid at 50° C. for 5 minutes, and then subjected again to rinsing with ultrapure water for 1 minute and drying by blowing with nitrogen (FIG. 1 (C)).

With regard to the evaluation substrate 4b thus obtained, an amount of IGZO etched was measured using a stylus profiler, and the E.R. was calculated from the immersion time and the amount of etching. Furthermore, the time taken for 50 nm IGZO to be etched in the thickness direction of the evaluation substrate was calculated from the E.R. thus obtained, the evaluation substrate was immersed for a time that was 2.0 times the above time, and the shape and residue after etching were examined using a scanning electron microscope. The pH and results for each etching solution composition are shown in Table 2. With regard to evaluation of residue after etching, a state without residue was evaluated as being ‘Good’, and a state with residue was evaluated as being ‘Poor’. The amount of side etching was a measurement of the length of section 5 in FIG. 1 (B).

TABLE 2
IGZO etching properties due to pH variation

| | | | Etching | Amount of | Evaluation of |
|---|---|---|---|---|---|
| | | | rate | side etching | post-etching |
| | | pH | (nm/min.) | (μm) | residue |
| Ex. | 10 | 1 | 180 | 0.09 | Good |
| | 11 | 2 | 68 | 0.09 | Good |
| | 12 | 3 | 21 | 0.1 | Good |
| | 13 | 4 | 12 | 0.09 | Good |
| Comp. | 12 | 5 | <10 | — | — |
| Ex. | 13 | 6 | <10 | — | — |
| | 14 | 8 | <10 | — | — |

In the table, ‘—’ denotes that measurement was impossible or evaluation was impossible.

### <Evaluation 3: IGZO Etching Properties Due to Variation of Acid Concentration>

An evaluation substrate 4 was prepared in the same way as for <Evaluation 1> (FIG. 1 (A)).

The evaluation substrate 4 was sectioned into 2.0 cm×2.0 cm pieces and immersed, while agitating, in a polyethylene container containing 50 mL of the etching solution composition at 35° C. for 10 to 60 seconds, and subjected to rinsing with ultrapure water for 1 minute and drying by blowing with nitrogen (FIG. 1 (B)).

The evaluation substrate 4a thus obtained was immersed, without agitating, in a glass container containing 50 mL of a resist stripping liquid at 50° C. for 5 minutes, and then subjected again to rinsing with ultrapure water for 1 minute and drying by blowing with nitrogen (FIG. 1 (C)).

With regard to the evaluation substrate 4b thus obtained, the amount of metal oxide etched was measured using a stylus profiler, and the E.R. was calculated from the immersion time and the amount of etching. Furthermore, the time taken for 50 nm IGZO to be etched in the thickness direction of the evaluation substrate was calculated from the E.R. thus obtained, the evaluation substrate was immersed for a time that was 2.0 times the above time, and the shape and residue after etching were examined using a scanning electron microscope. The etching solution compositions and results are shown in Table 3.

TABLE 3
IGZO etching properties due to variation of acid concentration

| | | | Etching | | | | |
|---|---|---|---|---|---|---|---|
| | | | solution | | Etching | Amount of | Evaluation of |
| | | | composition | Concentration | rate | side etching | post-etching |
| | | Acid | pH | (wt %) | (nm/min) | (μm) | residue |
| Ex. | 14 | Methanesulfonic | 0.4 | 4.7 | 52 | 0.09 | Good |
| | 15 | acid | 0.0 | 9.3 | 65 | 0.10 | Good |
| | 16 | | −0.5 | 26.3 | 68 | 0.10 | Good |
| | 17 | | −0.9 | 41.5 | 49 | 0.09 | Good |
| | 18 | | −1.3 | 58.2 | 28 | 0.09 | Good |
| Comp. | 15 | Hydrofluoric acid | 2.3 | 0.1 | 600 | 0.28 | Good |
| Ex. | 16 | | 2.3 | 1.0 | 3600 | 0.36 | Good |

### <Evaluation 4: IGZO Etching Properties Due to Combination of Acids>

An evaluation substrate 4 was prepared in the same way as for <Evaluation 1> (FIG. 1 (A)).

The evaluation substrate 4 was sectioned into 2.0 cm×2.0 cm pieces and immersed, while agitating, in a polyethylene container containing 50 mL of the etching solution composition at 35° C. for 10 to 60 seconds, and subjected to rinsing with ultrapure water for 1 minute and drying by blowing with nitrogen (FIG. 1 (B)).

The evaluation substrate 4a thus obtained was immersed, without agitating, in a glass container containing 50 mL of a resist stripping liquid at 50° C. for 5 minutes, and then subjected again to rinsing with ultrapure water for 1 minute and drying by blowing with nitrogen (FIG. 1 (C)).

With regard to the evaluation substrate 4b thus obtained, the amount of various types of metal oxide etched was measured using a stylus profiler, and the E.R. was calculated from the immersion time and the amount of etching. Furthermore, the time taken for 50 nm IGZO to be etched in the thickness direction of the evaluation substrate was calculated from the E.R. thus obtained, the evaluation substrate was immersed for a time that was 2.0 times the above time, and the shape and residue after etching were examined using a scanning electron microscope. The etching solution compositions and results are shown in Table 4. The pKa of methoxyacetic acid at 25° C. is 3.60.

TABLE 4
IGZO etching properties due to combination of acids

| | | | Etching | | | | |
|---|---|---|---|---|---|---|---|
| | | | solution | Acid | Etching | Amount of | Evaluation of |
| | | | composition | concentration | rate | side etching | post-etching |
| | | Combination of acids | pH | (wt %) | (nm/min.) | (μm) | residue |
| Ex. | 19 | Phosphoric acid | 0.9 | 6.0 | 85 | 0.09 | Good |
| | | Glycolic acid | | 10.0 | | | |
| | 20 | Phosphoric acid | 0.2 | 9.4 | 138 | 0.09 | Good |
| | | Nitric acid | | 3.0 | | | |
| | 21 | Nitric acid | −0.2 | 6.0 | 25 | 0.14 | Good |
| | | Methoxyacetic acid | | 21.2 | | | |
| | 22 | Methanesulfonic acid | −0.8 | 40.0 | 127 | 0.14 | Good |
| | | Oxalic acid | | 0.5 | | | |
| | 23 | Methanesulfonic acid | −0.1 | 9.1 | 150 | 0.15 | Good |
| | | Sulfuric acid | | 4.8 | | | |

| | | | | | | |
|---|---|---|---|---|---|---|
| Comp. | Hydrochloric acid | 0.3 | 1.7 | 500 | 0.27 | Good |
| Ex. 17 | Nitric acid | | 3.0 | | | |

### INDUSTRIAL APPLICABILITY

Since the etching solution composition of the present invention can control the etching rate so that it is practical for a metal oxide containing In and a metal oxide containing Zn and In using the same formulation, it enables mass production of a flat panel display, etc. used in a cell-phone, etc. to be carried out at low cost.

### EXPLANATION OF REFERENCE NUMERALS AND SYMBOLS

1 Glass substrate
2 Sputtered film formed from IZO or IGZO
2a Sputtered film formed from IZO or IGZO after etching
3 Resist on which resist patterning has been carried out
4 Evaluation substrate
4a Evaluation substrate after etching
4b Evaluation substrate stripped of resist after etching
5 Amount of side etching

1. An etching solution composition for etching a metal oxide containing indium (In) or a metal oxide containing zinc (Zn) and In, the composition comprising
at least one type of acid and water,
the acid having an acid dissociation constant pKa at 25° C. in any dissociation stage of no greater than 2.15,
and the composition having a hydrogen ion concentration pH at 25° C. of no greater than 4
(excluding an etching solution composition comprising a hydrohalic acid, a perhalic acid, KNO₃, CH₃COOK, KHSO₄, KH₂PO₄, K₂SO₄, K₂HPO₄, or K₃PO₄ and, in the case where the acid is oxalic acid, an etching solution composition comprising at least one type of compound selected from the group consisting of a polysulfonic acid compound, a polyoxyethylene-polyoxypropylene block copolymer, a naphthalenesulfonic acid condensation product, a quaternary ammonium hydroxide, an alkali metal hydroxide, an alkanolamine (excluding triethanolamine), a hydroxylamine, ammonium sulfate, ammonium sulfamate, and ammonium thiosulfate).

2. The etching solution composition according to claim 1, wherein the metal oxide further comprises at least one type of element selected from the group consisting of aluminum, gallium, and tin.

3. The etching solution composition according to claim 1, wherein the acid is a mineral acid, a sulfonic acid, or oxalic acid.

4. The etching solution composition according to claim 3, wherein the mineral acid is sulfuric acid, sulfamic acid, peroxomonosulfuric acid, phosphoric acid, phosphorous acid, hypophosphorous acid, or nitric acid.

5. The etching solution composition according to claim 3, wherein the sulfonic acid is methanesulfonic acid, ethanesulfonic acid, para-toluenesulfonic acid, camphorsulfonic acid, or a naphthalenesulfonic acid/formaldehyde condensation product.

6. The etching solution composition according to claim 1, wherein the etching rate in the thickness direction is at least 10 nm/min but no greater than 200 nm/min for both a layer comprising a metal oxide containing In and a layer comprising a metal oxide containing Zn and In.

7. The etching solution composition according to claim 1, wherein it does not comprise acetic acid.

8. The etching solution composition according to claim 1, wherein it further comprises a water-soluble organic solvent.

9. A method for etching a substrate having on the surface a layer comprising a metal oxide containing In or a metal oxide containing Zn and In using the etching solution composition according to claim 1.

10. A wiring board obtained by etching a substrate having on the surface a layer comprising a metal oxide containing In or a metal oxide containing Zn and In by the method according to claim 9.

11. A method for producing a wiring board, the method comprising a step of etching a substrate having on the surface a layer comprising a metal oxide containing In or a metal oxide containing Zn and In using the etching solution composition according to claim 1.
